(19) United States
(12) Patent Application Publication
(10) Pub. No.: US 2014/0183722 A1
(43) Pub. Date: Jul. 3, 2014

(54) SEMICONDUCTOR DEVICE AND METHOD FOR MANUFACTURING SAME

(71) Applicant: Panasonic Corporation, Osaka (JP)

(72) Inventors: Ryosuke Shiozaki, Kanagawa (JP); Suguru Fujita, Tokyo (JP); Shunsuke Hirano, Kanagawa (JP)

(73) Assignee: Panasonic Corporation, Osaka (JP)

(21) Appl. No.: 14/122,452

(22) PCT Filed: Dec. 21, 2012
(86) PCT No.: PCT/JP2012/008217

§ 371 Date: Nov. 26, 2013

(30) Foreign Application Priority Data
Dec. 28, 2011 (JP) 2011-288681

(51) Int. Cl. H01L 23/28; H01L 21/56

(52) U.S. Cl. CPC H01L 23/28; H01L 21/56
USPC 257/734; 438/124

(57) ABSTRACT

This semiconductor device, which has electronic components provided in a cavity of a module having a cavity structure, can be prevented from being increased in size. In the device, the module having the cavity structure is provided with a plurality of components, for instance, an IC (3) and chip components (6a, 6b), on one surface facing a motherboard (9), said one surface being on the cavity side. The motherboard (9) is provided with the chip components (6c, 6d) on parts of one surface facing the module having the cavity structure, said parts not having the components provided on the module surface having the components provided thereon.

### TECHNICAL FIELD

The present invention relates to a semiconductor device including an electronic component in a cavity of a cavity structure module and to a method for manufacturing the same.

### BACKGROUND ART

Heretofore, semiconductor devices including electronic components in a cavity (recessed portion) of a cavity structure module have been known (for example, PTL 1). PTL 1 discloses that, in a cavity structure module having a cavity formed by a base substrate and a supporting substrate, an electronic component is mounted on the cavity side of the base substrate.

In such a cavity of the cavity structure module, the electronic, component is mounted on the base substrate, and then a motherboard is bonded to the cavity side, and a semiconductor device is completed accordingly.

### CITATION LIST

### Patent Literature

PTL 1

International Publication No. WO2007/111290

### SUMMARY OF INVENTION

### Technical Problem

However, the above-mentioned configuration of the semiconductor device has the following problems which will be described hereinafter in details with reference to FIGS. 1A and 1B. FIGS. 1A and 1B show a configuration example of the above-mentioned semiconductor device; FIG. 1A is a cross-sectional view, and FIG. 1B is a diagram viewed from the motherboard side. Meanwhile, in FIG. 1B, longitudinal legs 2a and 2b are shown, and transverse legs are not shown.

As shown in FIGS. 1A and 1B, in a cavity structure module having a cavity formed by base substrate 1 and legs 2a and 2b, IC 3 and chip components 6a and 6b are mounted on base substrate 1. Here, underfill 5 is used to fill in an area between IC 3 and base substrate 1, but underfill 5 leaks around IC 3.

When underfill 5 leaks around IC 3, it is difficult to dispose a chip component on the portion where underfill 5 leaks. This portion ends up with being a useless space. As a result, the size of the cavity structure module increases, and in FIG. 1, chip components 6c and 6d are required to be disposed outside the cavity structure module. For this reason, an increase in the size of semiconductor devices becomes a problem.

An object of the present invention is to provide a semiconductor device including an electronic component in a cavity of a cavity structure module and being capable of avoiding an increase in the size of semiconductor device and also to provide a method for manufacturing the semiconductor device.

### Solution to Problem

A semiconductor device according to an aspect of the present invention includes: a structure module including a base substrate and a leg for disposing a component; and a motherboard to be bonded to the leg, in which: the structure module includes a plurality of components on one surface of the structure module, the one surface facing the motherboard; and the motherboard includes a component at a portion of one surface of the motherboard, the one surface facing the structure module, the portion corresponding to a portion where the plurality of components are not provided on the surface of the structure module where the plurality of components are provided.

A method for manufacturing a semiconductor device according to an aspect of the present invention is a method including a structure module including a base substrate and a leg for disposing a component, and a motherboard bonded to the leg, the method including: mounting a plurality of components on one surface of the structure module, the one surface facing the motherboard, mounting a component at a portion of one surface of the motherboard, the one surface facing the structure module, the portion corresponding to a portion where the plurality of components are not provided on the surface of the structure module where the plurality of components are provided; and bonding together the surface of the structure module where the components are mounted and the surface of the motherboard where the component is mounted in such a way that the surfaces of structure module and the motherboard face each other.

### ADVANTAGEOUS EFFECTS OF INVENTION

According to the present invention, it is possible to prevent an increase in size of a semiconductor device including an electronic component in a cavity structure module.

### BRIEF DESCRIPTION OF DRAWINGS

FIGS. 1A and 1B are a cross-sectional side view illustrating a configuration example of a semiconductor device according to the related art and a diagram viewed from below, respectively;

FIGS. 2A to 2I are diagrams illustrating example processes of a method for manufacturing a semiconductor device according to Embodiment 1 of the present invention;

FIGS. 3A and 3B are a cross-sectional side view illustrating a configuration example of a semiconductor device according to Embodiment 1 and a diagram viewed from below, respectively;

FIGS. 4A and 4B are diagrams each illustrating an example of how through holes of a cavity structure module according to Embodiment 2 of the present invention are formed;

FIG. 5 is a diagram illustrating an example of how sealing resin for the cavity structure module according to Embodiment 2 of the present invention is injected; and

FIG. 6 is a diagram illustrating an example of how chip components of a semiconductor device according to Embodiment 2 of the present invention are mounted.

### DESCRIPTION OF EMBODIMENTS

Hereinafter, embodiments of the present invention will be described in detail with reference to the accompanying drawings.

### Embodiment 1

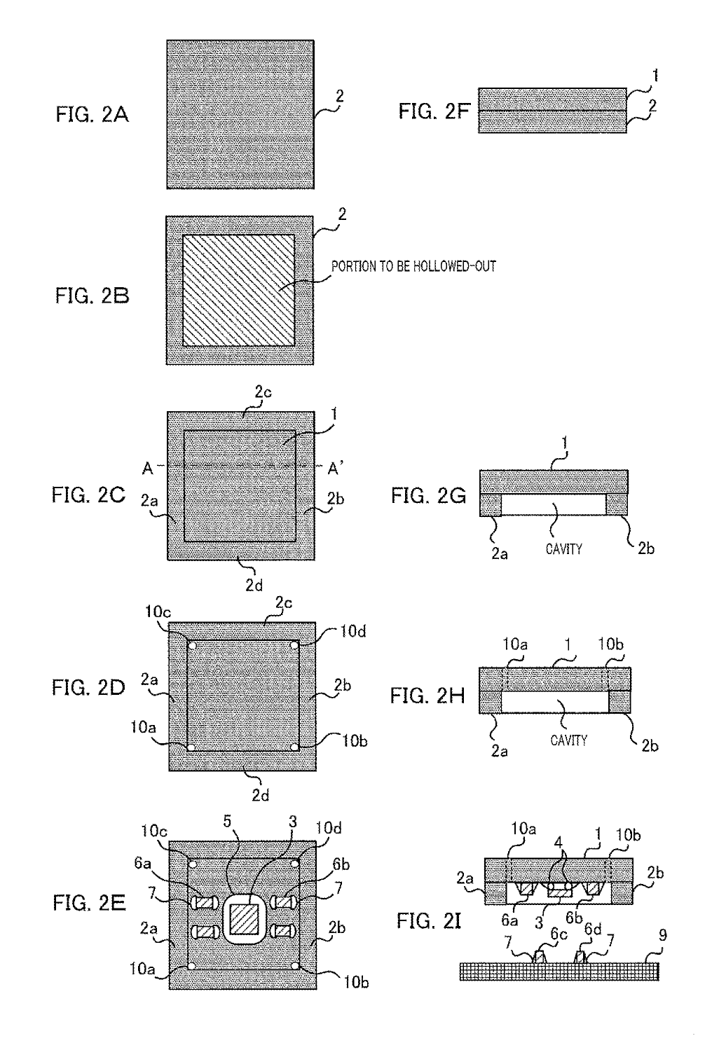

First, Embodiment 1 of the present invention will be described. FIGS. 2A to 2I are diagrams illustrating example processes of a method for manufacturing a semiconductor device in the present embodiment. Meanwhile, although the subject who performs the manufacturing method will be described below as a “manufacturer,” the term “manufacturer” as used herein is not limited to a human being and may include, for example, an apparatus.

First, the manufacturer bonds two substrates together to generate a double-sided substrate. FIG. 2F is a side view of the double-sided substrate. FIG. 2F illustrates the double-sided substrate in which base substrate 1 and substrate 2 are bonded to each other. FIG. 2A is a diagram when the double-sided substrate is viewed from the substrate 2 side. In FIG. 2A, the double-sided substrate is substantially square. Examples of the material of base substrate 1 and substrate 2 include glass epoxy.

Next, the manufacturer hollows out a portion to form a cavity (recessed portion) in substrate 2. For example, in FIG. 2B, the portion to be hollowed out which is shown by diagonal lines is removed from substrate 2. Next, FIG. 2C illustrates formed legs 2a, 2b, 2c, and 2d. A cavity structure module is created in which a space surrounded by base substrate 1 and legs 2a, 2b, 2c, and 2d serves as a cavity. FIG. 2G is a cross-sectional view taken along line A-N shown in FIG. 2C (the same is true of FIGS. 2H and 2I described later). Meanwhile, in FIG. 2G, illustration of legs 2c and 2d is omitted (the same applies to FIGS. 2H and 2I to be described later).

Next, the manufacturer forms a plurality of through holes connecting the outside and inside of the cavity in base substrate 1 of the generated cavity structure module. For example, in FIG. 2D, through holes 10a, 10b, 10e, and 10d are formed at four corners of base substrate 1 on the cavity side, respectively.

Through holes 10a, 10b, 10c, and 10d are used in vacuum drawing or the injection of sealing resin. Thus, in order to fill the cavity with sealing resin without any gaps, it is preferable that one through hole be formed in each of the four corners in FIG. 2D. However, the number of through holes or the positions thereof are not limited to this configuration. For example, when two through holes are formed, the two through holes may be diagonally formed at four corners of base substrate 1 on the cavity side. In FIG.

2D, these through holes may be formed by combination of through hole 10a and through hole 10d or through hole 10b and through hole 10c.

Next, the manufacturer solders various types of electronic components to one surface (surface facing motherboard 9) of base substrate 1 of the cavity structure module on the cavity side (where the cavity is formed). For example, in FIGS. 2E and 2I, IC 3 and chip components 6a and 6b are mounted on the cavity side of base substrate 1. Chip components 6a and 6b are mounted on base substrate 1 by solder 7. IC 3 is mounted on base substrate 1 via solder ball 4, and underfill 5 is used to fill in the gap between IC 3 and base substrate 1. Underfill 5 used herein leaks around IC 3. Note that, although chip components are not denoted by reference signs in FIG. 2E, chip components other than 6a and 6b are mounted.

Next, the manufacturer solders electronic components to the surface of a separately prepared motherboard which is bonded to the cavity side of the cavity structure module. For example, in FIG. 2I, chip components 6c and 6d are mounted on motherboard 9 by solder 7.

However, chip components 6c and 6d are not mounted to arbitrary positions on motherboard 9. That is, when motherboard 9 and the cavity structure module are bonded to each other, the mounting positions of chip components 6c and 6d are set to positions on motherboard 9 which correspond to (face) the whole or part of the leaking portion of underfill 5 on base substrate 1.

For example, in FIG. 2I, a position on motherboard 9 which corresponds to a space between IC 3 and chip component 6a is set to the mounting position of chip component 6c, and a position on motherboard 9 which corresponds to a space between IC 3 and chip component 6b is set to the mounting position of chip component 6d.

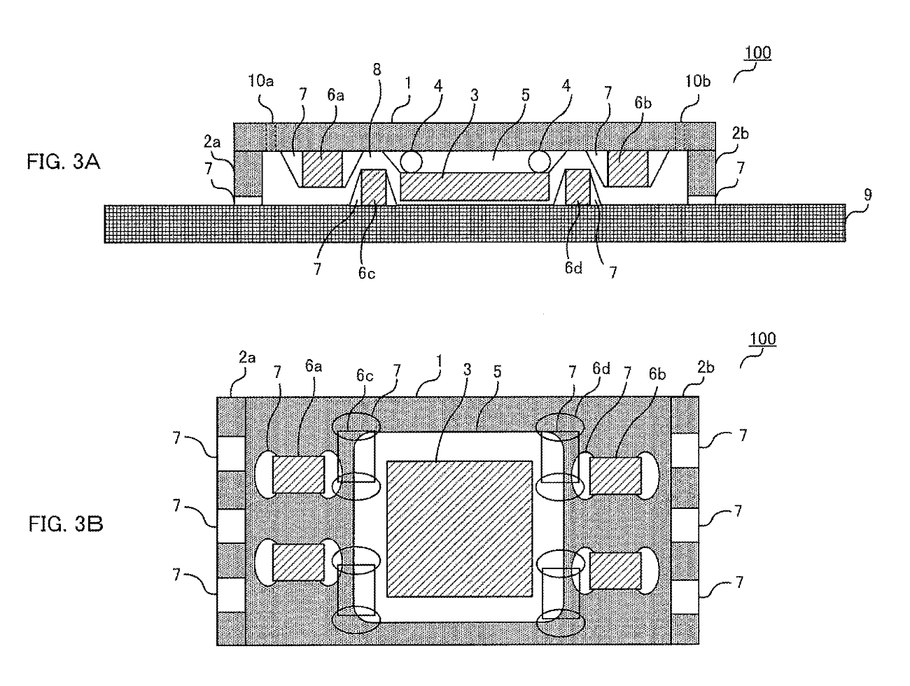

Next, the manufacturer bonds the cavity structure module having the electronic components mounted therein and motherboard 9 having the electronic components mounted therein. That is, the manufacturer bonds the component mounting surface of motherboard 9 (surface on which chip components 6c and 6d are mounted) to face the cavity side of the cavity structure module. At the time of the bonding, legs 2a, 2b, 2c, and 2d and motherboard 9 are soldered together (see FIG. 3A described later). Thereby, the cavity of the cavity structure module is hermetically sealed by motherboard 9.

Next, the manufacturer takes out the air of the hermetically sealed cavity (for example, space except the mounted electronic components) from, for example, through holes 10a and 10c, and further injects the sealing resin from; for example, through holes 10b and 10d. Thereby, the cavity is filled with the sealing resin (see FIG. 3A described later).

The semiconductor device of the present embodiment is completed through the above-mentioned processes. An example of the completed semiconductor device is shown in FIGS. 3A and 3B. FIG. 3A is a cross-sectional side view taken along line A-A′ of FIG. 2C, and FIG. 3B is a diagram illustrating the cavity structure module viewed from motherboard 9. Meanwhile, in FIG. 3B, leg 2c and leg 2d are not shown.

In FIGS. 3A and 3B, the cavity structure module is bonded to motherboard 9 through solder 7 attached to a portion of legs 2a, 2b, 2c, and 2d. In addition, the cavity (space except IC 3, underfill 5, chip components 6a, 6b, 6c, and 6d, and solder 7) hermetically sealed by motherboard 9 is filled with sealing resin 8. Meanwhile, each of through holes 10a, 10b, 10c, and 10d is filled with sealing resin 8.

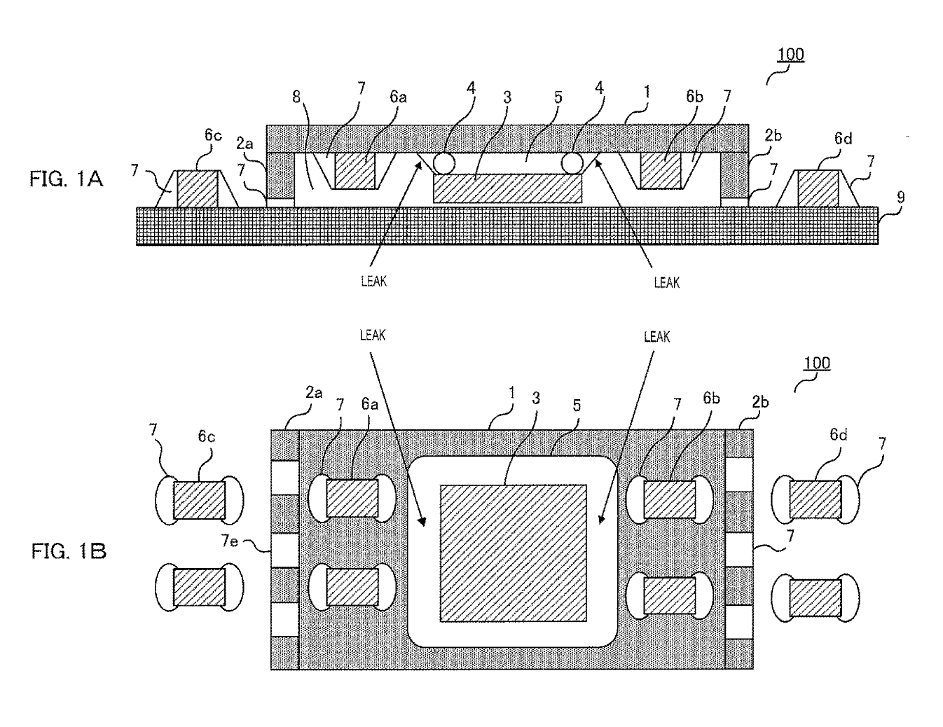

In FIGS. 3A and 3B, in semiconductor device 100, chip components 6c and 6d mounted outside a cavity structure module of the related art (see FIGS. 1A and 1B) are mounted in the cavity structure module. In addition, these chip components 6e and 6d are mounted in a space (gap) which is useless due to the leaking of underfill 5. Meanwhile, in FIG. 3B, the mounting direction of chip components 6c and 6d is the vertical direction while the mounting direction of chip components 6a and 6b is the horizontal direction.

Meanwhile, although not shown, signal lines are embedded in base substrate 1, legs 2a and 2b, and motherboard 9 in FIGS. 3A and 3B. Thereby, IC 3 and chip components 6a, 6b, 6c, and 6d have electrical connection with the signal lines through solder ball 4 or solder 7.

According to the present embodiment, electronic components are disposed in a space of the leaking portion of the underfill which has not been used in the related art in the inside (cavity) of the cavity structure module. Thus, the space in the cavity structure module is effectively used. Thereby, in the present embodiment, it is possible to avoid an increase in the size of the cavity structure module and also to reduce the number of electronic components disposed outside the cavity structure module. Therefore, it is possible to avoid an increase in the size of the semiconductor device.

Meanwhile, in the present embodiment, an example in which the through holes are formed in the base substrate has been described, but in the present invention, the cavity structure module having the electronic components mounted therein and the motherboard having the electronic components mounted thereon may be bonded together without forming the through holes. It is difficult to inject the sealing resin into the inside of the cavity structure module, but the electronic components are disposed in the space of the leaking portion of underfill which has not been used in the related art as mentioned above. The space of the inside of the cavity structure module can be effectively used.

However, since filling with the sealing resin is not performed, there arises a problem in that heat emitted from IC is not sufficiently dissipated from the inside of the cavity structure module. Therefore, as described with reference to FIGS. 2A to 2I, 3A, and 3B, it is preferable to form the through holes in the cavity structure module, and to fill the inside of the cavity structure module with the sealing resin.

In addition, in the present embodiment, the electronic components mounted on the motherboard are described as chip components (6c and 6d). However, in the present invention, the following components may be mounted as a substitute for the chip components.

For example, when the inside of the cavity structure module is not filled with the sealing resin, a metallic component (metal piece) having excellent thermal conductivity may be mounted. The effect of dissipating heat from the IC is obtained in this configuration.

For example, when the motherboard is formed in a multilayer structure, a multi-pin component may be mounted. An area in which the component is mounted can he reduced.

For example, since the motherboard allows more excellent heat dissipation than that of the cavity structure module, a component that emits heat may be mounted on the motherboard side.

For example, a bypass capacitor (bypass capacitor connected to a power supply pin of the IC) may be mounted thereon. Wiring (signal line embedded in the motherboard, the leg, and the base substrate) from the bypass capacitor to the IC increases in length, but an increase in the width of the wiring can cope with the increased length.

For example, a component which does not have direct electrical connection with a plurality of components of the cavity structure module may be mounted.

### Embodiment 2

Next, Embodiment 2 of the present invention will be described. In the present embodiment, the through hole is formed in the leg rather than the base substrate. The processes of the manufacturing method in Embodiment 2 are the same as those up to FIGS. 2A to 2C described in Embodiment 1. Thereafter, the manufacturer forms a plurality of through holes in any of legs 2a, 2h, 2c, and 2d of the cavity structure module.

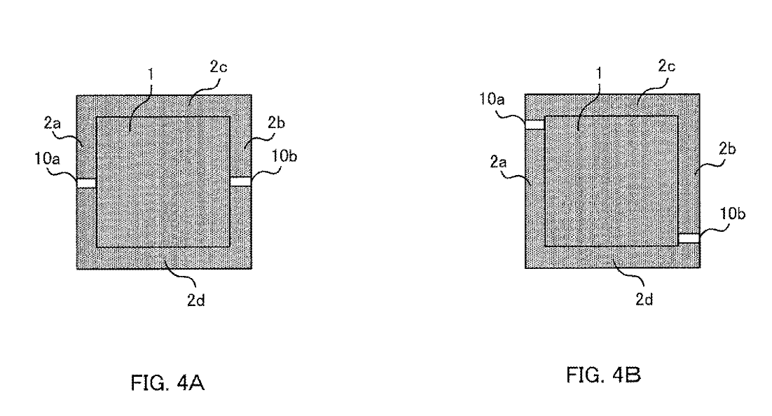

An example in which the through holes are formed is shown in FIGS. 4A and 4B. FIGS. 4A and 4B are diagrams when the cavity structure module is viewed from the cavity side. In the example of FIGS, 4A and 4B, through hole 10a is formed in leg 2a, and through hole 10b is formed in leg 10b. Positions at which through holes 10a and 10b are formed may be those shown in either FIG. 4A or FIG. 4B. For example, through hole 10a may be used in vacuum drawing, and through hole 10b may be used in the injection of the sealing resin.

Next, after the through holes are formed as mentioned above, the manufacturer solders various types of electronic components to the cavity side of base substrate 1 of the cavity structure module. The mounting of the electronic components is the same as that in Embodiment 1 (see FIGS. 2E and 2I).

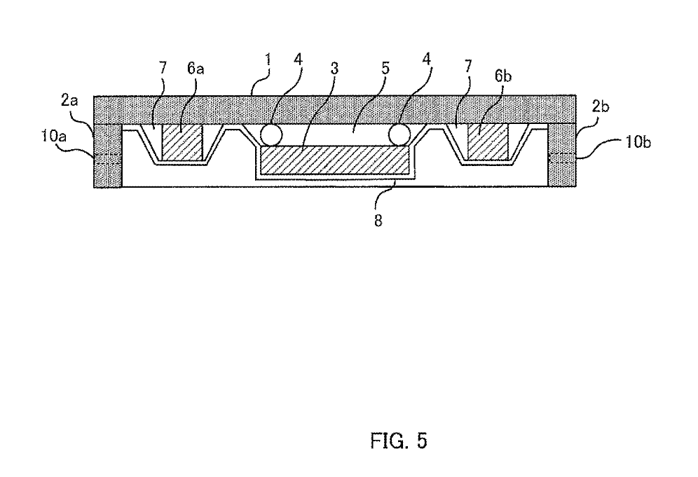

Next, the manufacturer injects sealing resin 8 so that sealing resin 8 is thinly formed at the mounting side of the electronic components of the cavity structure module, for example, as in FIG. 5. In the example of FIG. 5, unlike a manufacturing method for filling the entirety of the cavity with the sealing resin as in the related art, sealing resin 8 is injected so that sealing resin 8 is thinly formed on the surface of the electronic components (for example, IC 3, underfill 5, chip components 6a and 6b, solder 7) and a portion on which the electronic components are not mounted.

Next, the manufacturer bonds the cavity structure module shown in FIG. 5 and motherboard 9 having chip components 6c and 6d mounted thereon to each other by soldering, as is the case with Embodiment 1. Thereby, the cavity of the cavity structure module is hermetically sealed by motherboard 9.

Next, as is the case with Embodiment 1, the manufacturer performs vacuum drawing on the hermetically sealed cavity from through hole 10a, and further injects a material having good thermal conductivity from through hole 10b. Thereby, the inside of the cavity structure module is filled with the material having good thermal conductivity. Note that, each of through holes 10a and 10b is also filled with the material having good thermal conductivity. The semiconductor device of the present embodiment is completed through the above-mentioned processes. Thereby; for example, heat generated from IC 3 is dissipated from motherboard 9 through sealing resin 8 injected to form a thin thickness and the material having good thermal conductivity.

In the present embodiment, the same effect as that in Embodiment 1 is also obtained.

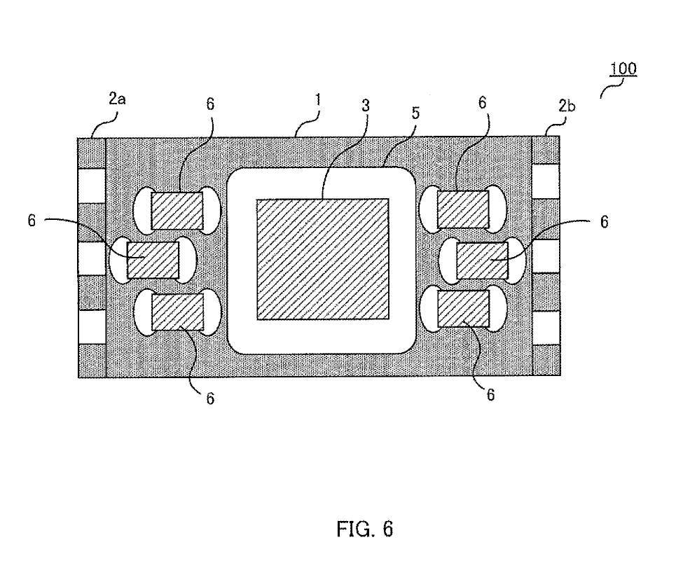

Meanwhile, in the present embodiment, as shown in FIG. 6, chip components 6 may be disposed in a zigzag, which in turn makes it possible to secure the clearance of a land for soldering, and to improve the mounting density of chip component 6.

In addition, in the present embodiment, the electronic components mounted on the motherboard may also be replaced by various components described in Embodiment 1 without being limited to the chip component. Meanwhile, in Embodiments 1 and 2, a portion formed by base substrate 1 and legs 2 is described as the cavity. However, when the leg is described as the cavity, the cavity structure module is formed using base substrate 1 and the cavity, and the electronic components are mounted on at least one of base substrate 1 and motherboard 9.

As stated above, although Embodiments 1 and 2 of the present invention have been described, the present invention is not limited to the description of any of the embodiments, and various changes and modifications can be made without departing from the spirit or scope of the invention.

A semiconductor device according to this disclosure includes: a structure module including a base substrate and a leg for disposing a component; and a motherboard to be bonded to the leg, in which: the structure module includes a plurality of components on one surface of the structure module, the one surface facing the motherboard; and the motherboard includes a component at a portion of one surface of the motherboard, the one surface facing the structure module, the portion corresponding to a portion where the plurality of components are not provided on the surface of the structure module where the plurality of components are provided.

In the semiconductor device according to this disclosure, the portion where the plurality of components are not provided includes an leaking portion of underfill, the leaking portion leaking from a predetermined component.

In the semiconductor device according to this disclosure: the structure module is hermetically scaled by bonding the structure module and the motherboard together; and the structure module includes a portion filled with a first sealing resin, the portion excluding the components provided to the structure module and the component provided to the motherboard.

In the semiconductor device according to this disclosure: the structure module is hermetically sealed by bonding the structure module and the motherboard together; the structure module includes a portion filled with a second sealing resin, the portion including surfaces of the plurality of components and the portion where the plurality of components are not provided on the surface of the structure module where the plurality of components are provided; and the structure module includes a portion being filled with a material having thermal conductivity, the portion excluding the components provided to the structure module, the second sealing resin, and the component provided to the motherboard.

In the semiconductor device according to this disclosure, the component provided in the motherboard is any one of a chip component, a metallic component having thermal conductivity, a component having multi-pins, a component that emits heat, a bypass capacitor, and a component which does not have direct electrical connection with the plurality of components of the structure module.

A method for manufacturing a semiconductor device according to this disclosure is a method including a structure module including a base substrate and a leg for disposing a component, and a motherboard bonded to the leg, the method including: mounting a plurality of components on one surface of the structure module, the one surface facing the motherboard; mounting a component at a portion of one surface of the motherboard, the one surface facing the structure module, the portion corresponding to a portion where the plurality of components are not provided on the surface of the structure module where the plurality of components are provided; and bonding together the surface of the structure module where the components are mounted and the surface of the motherboard where the component is mounted in such a way that the surfaces of structure module and the motherboard face each other.

The disclosure of Japanese Patent Application No. 2011-288681, filed on Dec. 28, 2011, including the specification, drawing and abstract, is incorporated herein, by reference in its entirety.

### INDUSTRIAL APPLICABILITY

The semiconductor device and the method for manufacturing the same according to the present invention are suitable for a general technique with which a component is provide in a cavity.

### REFERENCE SIGNS LIST

1 Base substrate
2 Substrate
2a, 2b, 2c, 2d Leg
3 IC
4 Solder ball
5 Underfill
6, 6a, 6b, 6c, 6d Chip component
7 Solder
8 Sealing resin
9 Motherboard
10a, 10b, 10c, 10d Through hole
100 Semiconductor device

1-6. (canceled)

7. A semiconductor device comprising:
a structure module including a base substrate and a leg for disposing a first component; and
a motherboard to be bonded to the leg, wherein:
the structure module includes the first component disposed on one surface of the structure module, the one surface facing the motherboard;
the one surface facing the motherboard and the first component are covered with a first sealing resin; and
the structure module includes a second sealing resin between the motherboard and the first sealing resin, the second sealing resin having higher thermal conductivity than the first sealing resin.

8. The semiconductor device according to claim 7, wherein the motherboard includes a second component disposed at a portion of one surface of the motherboard, the portion corresponding to a portion where the first component is not disposed, the one surface facing the structure module.

9. The semiconductor device according to claim 8, wherein the portion where the first component is not disposed includes an leaking portion of underfill, the leaking portion leaking from the first component.

10. The semiconductor device according to claim 8, wherein the second component is any one of a chip component, a metallic component having thermal conductivity, a component having multi-pins, a component that emits heat, a bypass capacitor, and a component which does not have direct electrical connection with the plurality of components of the structure module.

11. A method for manufacturing a semiconductor device, comprising:
disposing a first component on at least one surface of a structure module including a base substrate and a leg for disposing a first component;
covering the one surface on which the first component is disposed and the first component with a first sealing resin;
bonding together the motherboard and the surface of the structure module on which the first component is disposed; and
injecting a second sealing resin between the motherboard and the first sealing resin, the second sealing resin having higher thermal conductivity than the first sealing resin.

12. The method for manufacturing a semiconductor device according to claim 11, wherein the motherboard includes a second component disposed at a portion of a region of the motherboard, the portion corresponding to a portion where the first component is not disposed, the region of the motherboard being where the structure module is bonded.
